(19) United States
(12) Patent Application Publication
(10) Pub. No.: US 2017/0232510 A1
(43) Pub. Date: Aug. 17, 2017

(54) SILVER-COATED COPPER POWDER AND METHOD FOR PRODUCING SAME

(71) Applicant: Dowa Electronics Materials Co., Ltd., Tokyo (JP)

(72) Inventors: Noriaki Nogami, Tokyo (JP); Hiroshi Kamiga, Tokyo (JP)

(73) Assignee: Dowa Electronics Materials Co., Ltd., Tokyo (JP)

(21) Appl. No.: 15/501,880

(22) PCT Filed: Aug. 21, 2015
(86) PCT No.: PCT/JP2015/004197

§ 371 Date: Feb. 6, 2017

(30) Foreign Application Priority Data
Aug. 29, 2014 (JP) 2014-175342
Aug. 19, 2015 (JP) 2015-161498

(51) Int. Cl. B22F 1/02; C25D 3/48; C25D 5/34; C25D 7/00; H01L 31/0224; C23C 18/16; B05D 3/02; B05D 1/26; B05D 7/00; B22F 1/00; C23C 18/44

(52) U.S. Cl. CPC B22F 1/025; B22F 1/0014; C25D 3/48; C25D 5/34; C25D 7/00; C23C 18/44; C23C 18/1637; C23C 18/1653; B22F 1/0059; B05D 3/0254; B05D 1/26; B05D 7/00; H01L 31/022425; B22F 2301/10; B22F 2301/255; B22F 2302/45; B22F 2304/10; B22F 2998/10; B22F 2303/01

(57) ABSTRACT

There is provided a silver-coated copper powder, which has excellent storage stability (reliability), and a method for producing the same. A silver-coated copper powder obtained by coating the surface of a copper powder, which is obtained by the atomizing method or the like, with 5 wt % or more (with respect to the silver-coated copper powder) of a silver containing layer of silver or a silver compound, is added to a gold plating solution, which is a potassium gold cyanide solution (to which at least one of tripotassium citrate monohydrate, anhydrous citric acid and L-aspartic acid is preferably added), to cause 0.01 wt % or more (with respect to the silver-coated copper powder) of gold to be supported on the surface of the copper powder coated with the silver containing layer.

### TECHNICAL FIELD

The present invention relates generally to a silver-coated copper powder and a method for producing the same. More specifically, the invention relates to a silver-coated copper powder for use in electrically conductive pastes and so forth, and a method for producing the same.

### BACKGROUND ART

Conventionally, an electrically conductive paste prepared by mixing or compounding a solvent, a resin, a dispersing agent and so forth with an electrically conductive metal powder, such as silver or copper powder, is used for forming electrodes and electric wires of electronic parts by a printing method or the like.

However, silver powder increases the costs of the paste since it is a noble metal although it is a good electrically conductive material having a very low volume resistivity. On the other hand, the storage stability (reliability) of copper powder is inferior to that of silver powder since copper powder is easily oxidized although it is a good electrically conductive material having a low volume resistivity.

In order to solve these problems, as metal powders for use in electrically conductive pastes, there is proposed a silver-coated copper powder wherein the surface of copper powder is coated with silver (see, e.g., Patent Documents 1-2).

### PRIOR ART DOCUMENT(S)

### Patent Document(s)

Patent Document 1: Japanese Patent Laid-Open No. 2010-174311 (Paragraph Number 0003)
Patent Document 2: Japanese Patent Laid-Open No. 2010-077495 (Paragraph Number 0006)

### SUMMARY OF THE INVENTION

### Problem to be Solved by the Invention

However, in the silver-coated copper powder disclosed in Patent Documents 1-2, if a part of the surface of copper powder is not coated with silver, the oxidation of copper powder progresses from the part, so that the storage stability (reliability) of the silver-coated copper powder is insufficient.

It is therefore an object of the present invention to eliminate the aforementioned conventional problems and to provide a silver-coated copper powder which has excellent storage stability (reliability), and a method for producing the same.

### Means for Solving the Problem

In order to accomplish the aforementioned object, the inventors have diligently studied and found that it is possible to produce a silver-coated copper powder which has excellent storage stability (reliability), if a copper powder, the surface of which is coated with a silver containing layer, is added to a gold plating solution to cause gold to be supported on the surface of the copper powder coated with the silver containing layer. Thus, the inventors have made the present invention.

According to the present invention, there is provided a method for producing a silver-coated copper powder, the method comprising the steps of: preparing a copper powder, the surface of which is coated with a silver containing layer; and adding the copper powder to a gold plating solution to cause gold to be supported on the surface of the copper powder coated with the silver containing layer. In this method for producing a silver-coated copper powder, the silver containing layer is preferably a layer of silver or a silver compound. The amount of the silver containing layer with respect to the silver-coated copper powder is preferably 5% by weight or more, and the amount of gold with respect to the silver-coated copper powder is preferably 0.01% by weight or more. The gold plating solution preferably comprises a potassium gold cyanide solution, and more preferably comprises a potassium gold cyanide solution which contains at least one selected from the group consisting of tripotassium citrate monohydrate, anhydrous citric acid and L-aspartic acid. The particle diameter (D₅₀ diameter) corresponding to 50% of accumulation in cumulative distribution of the copper powder, which is measured by a laser diffraction particle size analyzer, is preferably in the range of from 0.1 μm to 15 μm.

According to the present invention, there is provided a silver-coated copper powder comprising: a copper powder coated with a silver containing layer; and gold supported on the surface of the copper powder coated with the silver containing layer. In this silver-coated copper powder, the silver containing layer is preferably a layer of silver or a silver compound. The amount of the silver containing layer with respect to the silver-coated copper powder is preferably 5% by weight or more, and the amount of gold with respect to the silver-coated copper powder is preferably 0.01% by weight or more. The particle diameter (D₅₀ diameter) corresponding to 50% of accumulation in cumulative distribution of the copper powder, which is measured by a laser diffraction particle size analyzer, is preferably in the range of from 0.1 μm to 15 μm.

According to the present invention, there is provided an electrically conductive paste wherein the above-described silver powder is used as an electric conductor. Alternatively, according to the present invention, there is provided an electrically conductive paste comprising: a solvent; a resin; and the above-described silver powder as an electrically conductive powder.

According to the present invention, there is provided a method for producing an electrode for solar cell, the method comprising the steps of: applying the above-described electrically conductive paste on a substrate; and curing the electrically conductive paste to form an electrode on the surface of the substrate.

### Effects of the Invention

According to the present invention, it is possible to provide a silver-coated copper powder which has excellent storage stability (reliability), and a method for producing the same.

### BRIEF DESCRIPTION OF THE DRAWINGS

FIG. 1 is a graph showing the percentage of increase of the weight of each of silver-coated copper powders obtained in Examples 1-5 and Comparative Example 1, with respect to heating temperature; and

FIG. 2 is a graph showing the variation in conversion efficiency of a solar cell produced using each of electrically conductive pastes in Example 9 and Comparative Example 2, with respect to time in a weather resistance test thereof.

### MODE FOR CARRYING OUT THE INVENTION

In the preferred embodiment of a method for producing a silver-coated copper powder according to the present invention, a copper powder, the surface of which is coated with a silver containing layer, is added to a gold plating solution to cause gold to be supported on the surface of the copper powder coated with the silver containing layer. If gold is thus caused to be supported on the surface of the copper powder coated with the silver containing layer, it is possible to coat the exposed portion of the copper powder, which is not coated with the silver containing layer, with gold to prevent the oxidation of the copper powder to produce a silver-coated copper powder having excellent storage stability (reliability).

The silver containing layer is preferably a layer of silver or a silver compound. The coating amount of the silver containing layer with respect to the silver-coated copper powder is preferably 5% by weight or more, more preferably in the range of from 7% by weight to 50% by weight, more preferably in the range of from 8% by weight to 40% by weight, and most preferably in the range of from 9% by weight to 20% by weight. If the coating amount of the silver containing layer is less than 5% by weight, it is not preferable since there is a bad influence on the electrical conductivity of the silver-coated copper powder. On the other hand, if the coating amount of the silver containing layer exceeds 50% by weight, it is not preferable since the costs are enhanced by the increase of silver to be used.

The supported amount of gold with respect to the silver-coated copper powder is preferably 0.01% by weight or more, and more preferably in the range of from 0.05% by weight to 0.7% by weight. If the supported amount of gold is less than 0.01% by weight, the exposed portion of the copper powder of the silver-coated copper powder, sufficiently covered with gold. If the supported amount of gold exceeds 0.7% by weight, it is not preferable since the proportion of improvement of the effect of preventing the oxidation of the copper powder with respect to the increased amount of gold is small and since the costs are enhanced.

The gold plating solution is preferably a solution which can gold-plate the exposed portion of the copper powder being not coated with silver and which does not dissolve the silver containing later therein, and preferably comprises a potassium gold cyanide solution. The gold plating solution may comprise any one of acidic, neutral and alkaline gold plating solutions, and preferably comprises an acidic potassium gold cyanide solution which contains an organic acid, such as citric acid. The gold plating solution further comprises a potassium gold cyanide solution which contains at least one selected from the group consisting of tripotassium citrate monohydrate, anhydrous citric acid and L-aspartic acid. The gold plating solution may contain cobalt as a brightening agent. Furthermore, a method for adding the copper powder, the surface of which is coated with the silver containing layer, to the gold plating solution may be any one of a method for mixing the gold plating solution with a dispersing solution wherein the copper powder coated with the silver containing layer is dispersed in a solvent, such as water, and so forth. When the copper powder coated with the silver containing layer is caused to contact the gold plating solution, the copper powder coated with the silver containing layer is preferably dispersed in the liquid. Immediately after the copper powder coated with the silver containing layer is added to the gold plating solution, the concentration of gold in the liquid is preferably in the range of from 0.0001 g/L to 5 g/L, and more preferably in the range of from 0.0002 g/L to 0.9 g/L. If the concentration of gold in the liquid is too high after the copper powder coated with the silver containing layer is added to the gold plating solution, it is not preferable since portions except for the exposed portion of the copper powder, which is not coated with silver, are coated with gold to increase the used amount of gold to enhance the costs.

With respect to the particle diameter of the copper powder, the particle diameter (D₅₀ diameter) corresponding to 50% of accumulation in cumulative distribution of the copper powder, which is measured by a laser diffraction particle size analyzer (by helos method), is preferably in the range of from 0.1 μm to 15 μm, more preferably in the range of from 0.3 μm to 10 μm, and most preferably in the range of from 1 μm to 5 μm. If the particle diameter (D₅₀ diameter) is less than 0.1 μm, it is not preferable since there is a bad influence on the electrical conductivity of the silver-coated copper powder. On the other hand, if the particle diameter (D₅₀ diameter) exceeds 15 μm, it is not preferable since it is difficult to form fine wires.

The copper powder may be produced by a wet reducing method, an electrolytic method, a gas phase method or the like, and is preferably produced by a so-called atomizing method (such as a gas atomizing method or a water atomizing method) for producing a fine powder by rapidly cooling and solidifying copper, which is melted at a temperature of not lower than the melting temperature thereof, by causing a high-pressure gas or high-pressure water to collide with the molten copper while causing the molten copper to drop from the lower portion of a tundish. In particular, if the copper powder is produced by a so-called water atomizing method for spraying a high-pressure water, it is possible to obtain a copper powder having small particle diameters, so that it is possible to improve the electrical conductivity of an electrically conductive paste due to the increase of the number of contact points between the particles when the copper powder is used for preparing the electrically conductive paste.

As a method for coating the copper powder with the silver containing layer, there may be used a method for depositing silver or a silver compound on the surface of a copper powder by a substitution method utilizing a substitution reaction of copper with silver or by a reduction method using a reducing agent. For example, there may be used a method for depositing silver or a silver compound on the surface of a copper powder while stirring a solution containing the copper powder and the silver or silver compound in a solvent, a method for depositing silver or a silver compound on the surface of a copper powder while stirring a mixed solution prepared by mixing a solution, which contains the copper powder and organic substances in a solvent, with a solution containing the silver or silver compound and organic substances in a solvent, and so forth.

As the solvent, there may be used water, an organic solvent or a mixed solvent thereof. If a solvent prepared by mixing water with an organic solvent is used, it is required to use an organic solvent which is liquid at room temperature (20 to 30° C.), and the mixing ratio of water to the organic solvent may be suitably adjusted in accordance with the used organic solvent. As water used as the solvent, there may be used distilled water, ion-exchanged water, industrial water or the like unless there is the possibility that impurities are mixed therein.

As raw materials of the silver containing layer, silver nitrate having a high solubility with respect to water and many organic solvents is preferably used since it is required to cause silver ions to exist in the solution. In order to carry out a method for coating the copper powder with the silver containing layer (silver coating reaction) as uniform as possible, a silver nitrate solution, which is prepared by dissolving silver nitrate in a solvent (water, an organic solvent or a mixed solvent thereof), not solid silver nitrate, is preferably used. The amount of the used silver nitrate solution, the concentration of silver nitrate in the silver nitrate solution, and the amount of the organic solvent may be determined in accordance with the amount of the intended silver containing layer.

In order to more uniformly form the silver containing layer, a chelating agent may be added to the solution. As the chelating agent, there is preferably used a chelating agent having a high complex formation constant with respect to copper ions and so forth, so as to prevent the reprecipitation of copper ions and so forth, which are formed as vice-generative products by a substitution reaction of silver ions with metallic copper. In particular, the chelating agent is preferably selected in view of the complex formation constant with respect to copper since the copper powder serving as the core of the silver-coated copper powder contains copper as a main composition element. Specifically, as the chelating agent, there may be used a chelating agent selected from the group consisting of ethylene-diamine-tetraacetic acid (EDTA), iminodiacetic acid, diethylene-triamine, triethylene-diamine, and salts thereof.

In order to stably and safely carry out the silver coating reaction, a buffer for pH may be added to the solution. As the buffer for pH, there may be used ammonium carbonate, ammonium hydrogen carbonate, ammonia water, sodium hydrogen carbonate or the like.

When the silver coating reaction is carried out, a solution containing a silver salt is preferably added to a solution in which the copper powder is sufficiently dispersed by stirring the solution after the copper powder is put therein before the silver salt is added thereto. The reaction temperature during this silver coating reaction may be a temperature at which the solidification and evaporation of the reaction solution are not caused. The reaction temperature is set to be preferably 10 to 40° C. and more preferably 15 to 35° C. The reaction time may be set in the range of from 1 minute to 5 hours although it varies in accordance with the coating amount of the silver or silver compound and the reaction temperature.

Furthermore, the shape of the copper powder coated with the silver containing layer (the shape of the silver-coated copper powder) may be substantially spherical or flake-shaped.

### EXAMPLES

Examples of a silver-coated copper powder and a method for producing the same according to the present invention will be described below in detail.

### Example 1

There was prepared a commercially available copper powder produced by atomizing (atomized copper powder SF-Cu (5 μm) produced by Nippon Atomized Metal Powders Corporation). The particle size distribution of this copper powder (before being coated with silver) was derived. As a result, the particle diameter (D₁₀) corresponding to 10% of accumulation in cumulative distribution of the copper powder was 2.26 μm, the particle diameter (D₅₀) corresponding to 50% of accumulation in cumulative distribution of the copper powder was 5.20 μm, and the particle diameter (D₉₀) corresponding to 90% of accumulation in cumulative distribution of the copper powder was 9.32 μm. Furthermore, the particle size distribution of the copper powder was measured by means of a laser diffraction particle size analyzer (Micro-Track Particle Size Distribution Measuring Apparatus MT-3300 produced by Nikkiso Co., Ltd.) for deriving the particle diameters D₁₀, D₅₀ and D₉₀ of the copper powder.

Then, a solution (solution 1) was prepared by dissolving 1470 g of EDTA-4Na (43%) and 1820 g of ammonium carbonate in 2882 g of pure water, and a solution (solution 2) was prepared by adding 235.4 g of an aqueous silver nitrate solution containing 77.8 g of silver to a solution prepared by dissolving 1470 g of EDTA-4Na (43%) and 350 g of ammonium carbonate in 2270 g of pure water.

Then, under a nitrogen atmosphere, 700 g of the above-described copper powder was added to the solution 1, and the temperature of the solution was raised to 35° C. while the solution was stirred. Then, the solution 2 was added to the solution in which the copper powder was dispersed, and the solution was stirred for 30 minutes. Thereafter, the solution was filtered, washed with water, and dried to obtain a copper powder coated with silver (a silver-coated copper powder).

Then, 0.5 g of the silver-coated copper powder thus obtained was added to 8 g of pure water to be added to 0.1 mL of a gold plating solution (acidic gold plating solution) to be stirred at room temperature for 30 minutes. Thereafter, the solution was filtrated while sprinkling water for extrusion. Then, a solid content on the filter paper was washed with pure water, and dried at 70° C. for 5 hours by means of a vacuum drier to obtain a silver-coated copper powder having gold supported on the surface thereof. Furthermore, as the gold plating solution, there was used a gold plating solution wherein additives for initial make-up of electrolytic bath were added to a potassium gold cyanide solution containing 20 g/L of gold, the additive comprising 50% by weight of tripotassium citrate monohydrate, 38.9% by weight of anhydrous citric acid, 10% by weight of L-aspartic acid and 1.1% by weight of cobalt sulfate. The amount of the filtrate was 77.7 g, and the concentration of each of Au, Ag and Cu in the filtrate was measured by means of an inductively coupled plasma (ICP) mass spectrometer (ICP-MS). As a result, the concentration of Au was less than 1 mg/L, the concentration of Ag was less than 1 mg/L, and the concentration of Cu was 120 mg/L.

After the silver-coated copper powder (having gold supported on the surface thereof) thus obtained was dissolved in aqua regia, pure water was added thereto to be filtrated to collect silver as silver nitrate. Then, the content of Au in the filtrate was measured by means of the ICP mass spectrometer (ICP-MS), and the content of Ag was derived from collected silver nitride by gravimetric method. As a result, the content of Au in the silver-coated copper powder was 0.60% by weight, and the content of Ag in the silver-coated copper powder was 11.0% by weight.

Then, the storage stability (reliability) of the silver-coated copper powder (having gold supported on the surface thereof) thus obtained was evaluated by evaluating the high-temperature stability thereof. The evaluation of the high-temperature stability of the silver-coated copper powder (having gold supported on the surface thereof) was carried out as follows. First, a thermo gravimetry differential thermal analyzer (TG-DTA) was used for deriving a difference (the weight of the silver-coated copper powder increased by heating) between the weight of the silver-coated copper powder (having gold supported on the surface thereof), which was measured at a temperature of each of 200° C., 250° C., 300° C., 350° C. and 400° C. when the temperature thereof was raised at a temperature raising rate of 10° C./min from room temperature (25° C.) to 400° C. in the atmosphere, and the weight (40 mg) of the silver-coated copper powder which was measured before the heating. Then, the analyzer was used for deriving a percentage (%) of increase of the weight as a percentage (%) of increase of the difference (the weight of the silver-coated copper powder increased by the heating) with respect to the weight of the silver-coated copper powder before the heating. The high-temperature stability of the silver-coated copper powder (against oxidation) in the atmosphere was evaluated on the basis of the percentage (%) of increase of the weight assuming that all of the weight of the silver-coated copper powder increased by the heating was the weight of the silver-coated copper powder increased by oxidation. As a result, the percentage of increase of the weight at each of 200° C., 250° C., 300° C. and 350° C. was 0.10%, 0.08%, 0.37% and 1.96%, respectively.

### Example 2

A silver-coated copper powder having gold supported on the surface thereof was obtained by the same method as that in Example 1, except that 3 g of the silver-coated copper powder obtained in Example 1 was added to 15 g of pure water and that the amount of the gold plating solution was 0.55 mL. Furthermore, the amount of the filtrate was 123.65 g. The concentration of each of Au, Ag and Cu in the filtrate was measured by the same method as that in Example 1. As a result, the concentration of Au was less than 1 mg/L, the concentration of Ag was less than 1 mg/L, and the concentration of Cu was 66 mg/L.

The content of each of Au and Ag in the silver-coated copper powder (having gold supported on the surface thereof) thus obtained was measured by the same method as that in Example 1. As a result, the content of Au was 0.30% by weight, and the content of Ag was 11.0% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.11%, 0.10%, 0.63% and 2.63%, respectively.

### Example 3

A silver-coated copper powder having gold supported on the surface thereof was obtained by the same method as that in Example 1, except that 3 g of the silver-coated copper powder obtained in Example 1 was added to 15 g of pure water and that the amount of the gold plating solution was 0.25 mL. Furthermore, the amount of the filtrate was 74.74 g. The concentration of each of Au, Ag and Cu in the filtrate was measured by the same method as that in Example 1. As a result, the concentration of Au was less than 1 mg/L, the concentration of Ag was less than 1 mg/L, and the concentration of Cu was 99 mg/L.

The content of each of Au and Ag in the silver-coated copper powder (having gold supported on the surface thereof) thus obtained was measured by the same method as that in Example 1. As a result, the content of Au was 0.16% by weight, and the content of Ag was 10.1% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.10%, 0.17%, 0.88% and 3.26%, respectively.

### Example 4

A silver-coated copper powder having gold supported on the surface thereof was obtained by the same method as that in Example 1, except that 5 g of the silver-coated copper powder obtained in Example 1 was added to 15 g of pure water and that the amount of the gold plating solution was 0.25 mL. Furthermore, the amount of the filtrate was 110.5 g. The concentration of each of Au, Ag and Cu in the filtrate was measured by the same method as that in Example 1. As a result, the concentration of Au was less than 1 mg/L, the concentration of Ag was less than 1 mg/L, and the concentration of Cu was 110 mg/L.

The content of each of Au and Ag in the silver-coated copper powder (having gold supported on the surface thereof) thus obtained was measured by the same method as that in Example 1. As a result, the content of Au was 0.09% by weight, and the content of Ag was 10.1% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.09%, 0.21%, 0.87% and 3.36%, respectively.

### Example 5

A silver-coated copper powder having gold supported on the surface thereof was obtained by the same method as that in Example 1, except that 7 g of the silver-coated copper powder obtained in Example 1 was added to 15 g of pure water to be added to 0.25 mL of a gold plating solution comprising a potassium gold cyanide solution containing 49 g/L of gold. Furthermore, the amount of the filtrate was 84.82 g. The concentration of each of Au, Ag and Cu in the filtrate was measured by the same method as that in Example 1. As a result, the concentration of Au was 5 mg/L, the concentration of Ag was less than 1 mg/L, and the concentration of Cu was 4 mg/L. In this example, the gold plating solution was not acidic since citric acid or the like was not added thereto. For that reason, it was not easy to allow the reaction to proceed, so that Au existed in the filtrate.

The content of each of Au and Ag in the silver-coated copper powder (having gold supported on the surface thereof) thus obtained was measured by the same method as that in Example 1. As a result, the content of Au was 0.17% by weight, and the content of Ag was 10.1% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.06%, 0.24%, 1.07% and 3.34%, respectively.

### Example 6

A silver-coated copper powder having gold supported on the surface thereof was obtained by the same method as that in Example 1, except that 1 mL of a gold plating solution distributed from a solution containing 0.91 g of a potassium gold cyanide solution containing 10 g/L of gold, 1.87 g of tripotassium citrate monohydrate and 0.07 g of anhydrous citric acid was used as the gold plating solution and that 3 g of the silver-coated copper power obtained in Example 1 was added to 15 g of pure water. Furthermore, the amount of the filtrate was 100.57 g. The concentration of each of Au, Ag and Cu in the filtrate was measured by the same method as that in Example 1. As a result, the concentration of Au was less than 1 mg/L, the concentration of Ag was less than 1 mg/L, and the concentration of Cu was 83 mg/L.

The content of each of Au and Ag in the silver-coated copper powder (having gold supported on the surface thereof) thus obtained was measured by the same method as that in Example 1. As a result, the content of Au was 0.70% by weight, and the content of Ag was 10.9% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.13%, 0.13%, 0.81% and 2.95%, respectively.

### Example 7

A silver-coated copper powder having gold supported on the surface thereof was obtained by the same method as that in Example 1, except that 1 mL of a gold plating solution distributed from a solution prepared by adding 0.05 g of tripotassium citrate monohydrate and 0.041 g of anhydrous citric acid to 5 mL of a potassium gold cyanide solution containing 10 g/L of gold was used as the gold plating solution and that 10 g of the silver-coated copper power obtained in Example 1 was added to 15 g of pure water. Furthermore, the amount of the filtrate was 123.9 g. The concentration of each of Au, Ag and Cu in the filtrate was measured by the same method as that in Example 1. As a result, the concentration of Au was less than 1 mg/L, the concentration of Ag was less than 1 mg/L, and the concentration of Cu was 120 mg/L.

The content of each of Au and Ag in the silver-coated copper powder (having gold supported on the surface thereof) thus obtained was measured by the same method as that in Example 1. As a result, the content of Au was 0.01% by weight, and the content of Ag was 10.1% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.15%, 0.31%, 0.99% and 3.52%, respectively.

### Example 8

A silver-coated copper powder having gold supported on the surface thereof was obtained by the same method as that in Example 1, except that 1 mL of a gold plating solution distributed from a solution prepared by adding 0.05 g of tripotassium citrate monohydrate, 0.041 g of anhydrous citric acid and 0.085 g of L-aspartic acid to 5 mL of a potassium gold cyanide solution containing 10 g/L of gold was used as the gold plating solution and that 10 g of the silver-coated copper power obtained in Example 1 was added to 15 g of pure water. Furthermore, the amount of the filtrate was 88 g. The concentration of each of Au, Ag and Cu in the filtrate was measured by the same method as that in Example 1. As a result, the concentration of Au was less than 1 mg/L, the concentration of Ag was less than 1 mg/L, and the concentration of Cu was 140 mg/L.

The content of each of Au and Ag in the silver-coated copper powder (having gold supported on the surface thereof) thus obtained was measured by the same method as that in Example 1. As a result, the content of Au was 0.01% by weight, and the content of Ag was 10.3% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.14%, 0.28%, 0.96% and 3.57%, respectively.

### Comparative Example 1

The content of Ag in the silver-coated copper powder (having no gold supported on the surface thereof without being added to the gold plating solution) obtained in Example 1 was measured by the same method as that in Example 1. As a result, the content of Ag was 10.9% by weight. The percentage of increase of the weight of the silver-coated copper powder at each of 200° C., 250° C., 300° C. and 350° C. was derived by the same method as that in Example 1. As a result, the percentage of increase of the weight thereof was 0.16%, 0.46%, 1.27% and 3.80%, respectively.

### Comparative Example 2

There was prepared a commercially available copper powder produced by atomizing (atomized copper powder SFR-5 μm produced by Nippon Atomized Metal Powders Corporation). The particle size distribution of this copper powder was derived by the same method as that in Example 1. As a result, the particle diameter D₁₀ of the copper powder was 2.12 μm, the particle diameter D₅₀ of the copper powder was 4.93 μm, and the particle diameter D₉₀ of the copper powder was 10.09 μm.

Then, a solution (solution 1) was prepared by adding 123.89 g of an aqueous silver nitrate solution containing 38.89 g of silver to a solution prepared by dissolving 337.83 g of EDTA-4Na (43%) and 9.1 g of ammonium carbonate in 1266.3 g of pure water, and a solution (solution 2) was prepared by dissolving 735 g of EDTA-4Na (43%) and 175 g of ammonium carbonate in 1133.85 g of pure water.

Then, under a nitrogen atmosphere, 350 g of the above-described copper powder was added to the solution 1, and the temperature of the solution was raised to 35° C. while the solution was stirred. Then, the solution 2 was added to the solution in which the copper powder was dispersed, and the solution was stirred for 30 minutes. Thereafter, the solution was filtered, washed with water, and dried to obtain a copper powder coated with silver (a silver-coated copper powder). The content of Ag in the silver-coated copper powder was measured by the same method as that in Example 1. As a result, the content of Ag was 10.1% by weight.

The percentage of increase of the weight of the obtained silver-coated copper powder at each of 200° C., 250° C., 300° C. and 350° C. was derived by the same method as that in Example 1. As a result, the percentage of increase of the weight thereof was 0.22%, 0.46%, 1.07% and 2.74%, respectively.

### Example 9

First, 1.4633 g of potassium gold cyanide (produced by Kojima Chemicals Co., Ltd.), 0.8211 g of anhydrous citric acid (produced by Wako Pure Chemical Industries, Ltd.), 0.1708 g of L-aspartic acid (produced by Wako Pure Chemical Industries, Ltd.) and 0.9998 g of tripotassium citrate monohydrate were added to 100 g of pure water to be stirred at 30° C. for 11 minutes to prepare a gold plating solution.

Then, 100 g of the silver-coated copper powder obtained in Comparative Example 2 was added to 150 g of pure water, and 10.299 g of the above-described gold plating solution was added thereto to be stirred at 30° C. for 30 minutes. Thereafter, the solution was filtrated while sprinkling water for extrusion. Then, a solid content on the filter paper was washed with pure water, and dried at 70° C. for 5 hours by means of a vacuum drier to obtain a silver-coated copper powder having gold supported on the surface thereof. Furthermore, the amount of the filtrate was 650 g. The concentration of each of Au, Ag and Cu in the filtrate was measured by the same method as that in Example 1. As a result, the concentration of Au was 2 mg/L, the concentration of Ag was less than 1 mg/L, and the concentration of Cu was 150 mg/L.

The content of each of Au and Ag in the silver-coated copper powder (having gold supported on the surface thereof) thus obtained was measured by the same method as that in Example 1. As a result, the content of Au was 0.10% by weight, and the content of Ag was 10.0% by weight.

The percentage of increase of the weight of the obtained silver-coated copper powder (having gold supported on the surface thereof) at each of 200° C., 250° C., 300° C. and 350° C. was derived by the same method as that in Example 1. As a result, the percentage of increase of the weight thereof was 0.13%, 0.27%, 0.80% and 2.27%, respectively.

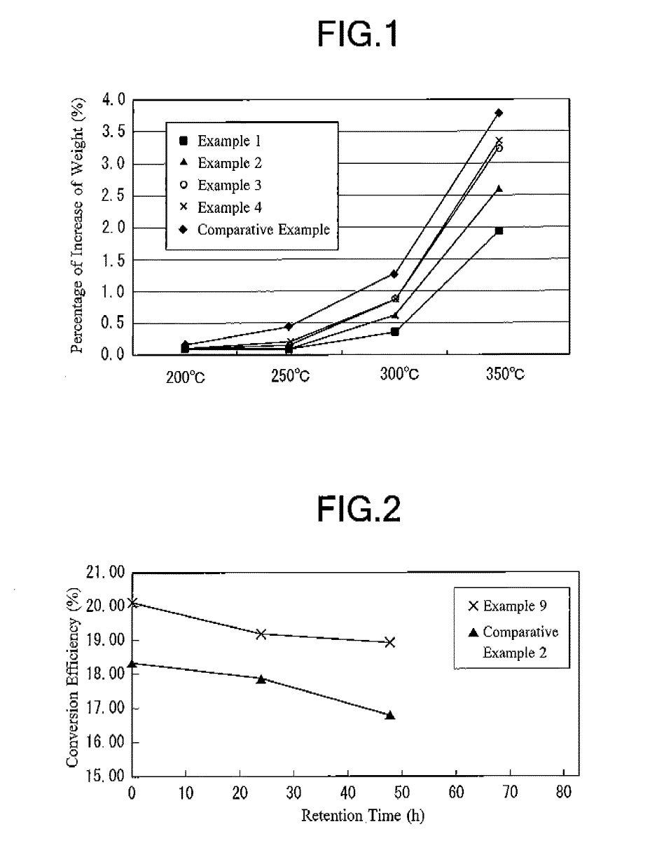

The producing conditions and characteristics of the silver-coated copper powders obtained in these examples and comparative examples are shown in Tables 1-3. FIG. 1 shows the percentage of increase of the weight of each of the silver-coated copper powders obtained in Examples 1-5 and Comparative Example 1 with respect to temperature.

TABLE 1

| | Silver-coated | Pure | Amount of | |
|---|---|---|---|---|
| | copper powder | Water | Plating | |
| | (g) | (g) | Solution | |
| Example 1 | 0.5 | 8 | 0.1 | mL |
| Example 2 | 3 | 15 | 0.55 | mL |
| Example 3 | 3 | 15 | 0.25 | mL |
| Example 4 | 5 | 15 | 0.25 | mL |
| Example 5 | 7 | 15 | 0.25 | mL |
| Example 6 | 3 | 15 | 1 | mL |
| Example 7 | 10 | 15 | 1 | mL |
| Example 8 | 10 | 15 | 1 | mL |
| Comparative Example 1 | — | — | — | |
| Comparative Example 2 | — | — | — | |
| Example 9 | 100 | 150 | 10.299 | g |

TABLE 2

| | Filtrate | | | | Silver-coated | |
|---|---|---|---|---|---|---|
| | Amount | | | | copper powder | |
| | of Liquid | Au | Ag | Cu | Au | Ag |
| | (g) | (mg/L) | (mg/L) | (mg/L) | (wt %) | (wt %) |
| Ex. 1 | 77.7 | <1 | <1 | 120 | 0.60 | 11.0 |
| Ex. 2 | 123.65 | <1 | <1 | 66 | 0.30 | 11.0 |
| Ex. 3 | 75.74 | <1 | <1 | 99 | 0.16 | 10.1 |
| Ex. 4 | 110.5 | <1 | <1 | 110 | 0.09 | 10.1 |
| Ex. 5 | 84.82 | 5 | <1 | 4 | 0.17 | 10.1 |
| Ex. 6 | 100.57 | <1 | <1 | 83 | 0.70 | 10.9 |
| Ex. 7 | 123.9 | <1 | <1 | 120 | 0.01 | 10.1 |
| Ex. 8 | 88 | <1 | <1 | 140 | 0.01 | 10.3 |
| Comp. 1 | — | — | — | — | — | 10.9 |
| Comp. 2 | — | — | — | — | — | 10.1 |
| Ex. 9 | 650 | 2 | <1 | 150 | 0.10 | 10.0 |

TABLE 3

Percentage of Increase of Weight (%)

| | 200° C. | 250° C. | 300° C. | 350° C. |
|---|---|---|---|---|
| Ex. 1 | 0.10 | 0.08 | 0.37 | 1.96 |
| Ex. 2 | 0.11 | 0.10 | 0.63 | 2.63 |
| Ex. 3 | 0.10 | 0.17 | 0.88 | 3.26 |
| Ex. 4 | 0.09 | 0.21 | 0.87 | 3.36 |
| Ex. 5 | 0.06 | 0.24 | 1.07 | 3.34 |
| Ex. 6 | 0.13 | 0.13 | 0.81 | 2.95 |
| Ex. 7 | 0.15 | 0.31 | 0.99 | 3.52 |
| Ex. 8 | 0.14 | 0.28 | 0.96 | 3.57 |
| Comp. 1 | 0.16 | 0.46 | 1.27 | 3.80 |
| Comp. 2 | 0.22 | 0.46 | 1.07 | 2.74 |
| Ex. 9 | 0.13 | 0.27 | 0.80 | 2.27 |

As shown in Tables 1-3 and FIG. 1, in the silver-coated copper powder having gold supported on the surface thereof in each of the examples, the percentage of increase of the weight thereof after heating in the atmosphere can be smaller than that of the silver-coated copper powder having no gold supported on the surface thereof in each of the comparative examples. For that reason, it can be seen that it is possible to improve the resistance to oxidation, so that the storage stability (reliability) thereof is excellent.

The filtrate obtained during the production of the silver-coated copper powder having gold supported on the surface thereof in each of the examples has a very low concentration of Ag and a high concentration of Cu, so that it is supposed that the exposed portion of the copper powder, which is not coated with silver, is selectively plated with gold. Therefore, the exposed portion of the copper powder, which is not coated with silver, can be covered with a very small amount of gold to improve the resistance to oxidation of the silver-coated copper powder, so that it is possible to produce a silver-coated powder having excellent storage stability (reliability).

After 87.0% by weight of the silver powder in each of Comparative Example 2 and Example 9, 3.8% by weight of an epoxy resin (JER1256 produced by Mitsubishi Chemicals Corporation), 8.6% by weight of butyl carbitol acetate (produced by Wako Pure Chemical Industries, Ltd.) serving as a solvent, 0.5% by weight of a curing agent (M-24 produced by Ajinomoto Fine-Techno Co., Inc.) and 0.1% by weight of oleic acid (produced by Wako Pure Chemical Industries, Ltd.) serving as a dispersing agent were mixed (preliminarily kneaded) by means of a planetary centrifugal vacuum degassing mixer (Awatori Rentaro produced by Thinky Corporation), the obtained mixture was kneaded by means of a three-roll mill (EXAKT 80S produced by Otto Hermann Inc.) to obtain an electrically conductive paste 1.

In addition, 45 L of industrial ammonia water was added to 502.7 L of a silver nitrate solution containing 21.4 g/L of silver ions to form a silver ammine complex solution. The pH of the formed silver ammine complex solution was adjusted by adding 8.8 L of a sodium hydroxide solution containing 100 g/L of sodium hydroxide thereto. This solution was distilled by adding 462 L of water thereto, and 48 L of industrial formalin serving as a reducing agent was added thereto. Immediately thereafter, 121 g of a stearic acid emulsion containing 16% by weight of stearic acid was added thereto. After a silver slurry thus obtained was filtered and washed with water, it was dried to obtain 21.6 kg of a silver powder. After the surface smoothing treatment of this silver powder was carried out by means of a Henschel mixer (high-speed mixer), the classification thereof was carried out to remove large aggregates of silver being larger than 11 μm.

Then, after 85.4% by weight of the silver powder thus obtained, 1.2% by weight of ethyl cellulose (produced by Wako Pure Chemical Industries, Ltd.), 7.9% by weight of a solvent (a mixed solvent containing texanol (produced by JMC Co., Ltd.) and butyl carbitol acetate (produced by Wako Pure Chemical Industries, Ltd.) at 1:1), and 1.5% by weight of a glass frit (ASF-1898B produced by Asahi Glass Co., Ltd.) and 3.2% by weight of tellurium dioxide (produced by Wako Pure Chemical Industries, Ltd.) serving as additives were mixed (preliminarily kneaded) by means of a planetary centrifugal vacuum degassing mixer (Awatori Rentaro produced by Thinky Corporation), the obtained mixture was kneaded by means of a three-roll mill (EXAKT 80S produced by Otto Hermann Inc.) to obtain an electrically conductive paste 2.

Then, two silicon wafers (produced by E&M Co., Ltd, 80 Ω/square, 6 inches monocrystal) were prepared. After an aluminum paste (ALSOLAR 14-7021 produced by Toyo Aluminum K.K.) was printed on the backside of each of the silicon wafers by means of a screen printing machine (MT-320T produced by Micro-tech Co., Ltd.), it was dried at 200° C. for 10 minutes by means of a hot air type dryer. Then, after the above-described electrically conductive paste 2 was printed on the surface (front side) of each of the silicon wafers in the shape of 100 finger electrodes, each having a width of 50 μm, by means of the screen printing machine (MT-320T produced by Micro-tech Co., Ltd.), it was dried at 200° C. for 10 minutes by means of the hot air type dryer, and then, it was fired at a peak temperature of 820° C. for an in-out time of 21 seconds in a fast firing IR furnace (Fast Firing Test Four-Chamber Furnace produced by NGK Insulators Ltd.). Thereafter, the electrically conductive paste 1 (the electrically conductive paste 1 produced from the silver-coated copper powder in each of Comparative Example 2 and Example 9) was printed on the surface (front side) of each of the silicon wafers in the shape of three busbar electrodes, each having a width of 1.3 mm, by means of the screen printing machine (MT-320T produced by Micro-tech Co., Ltd.), and then, it was dried at 200° C. for 40 minutes by means of the hot air type dryer and cured to produce a solar cell.

Then, a battery characteristic test was carried out by irradiating the above-described solar cell with pseudo sunlight having a light irradiation energy of 100 mWcm² by means of a xenon lamp of a solar simulator (produced by Wacom Electric Co., Ltd.). As a result, the conversion efficiency Eff of the solar cell produced using the electrically conductive paste in each of Comparative Example 2 and Example 9 was 18.34% and 20.12%, respectively.

As the weather resistance test (reliability test), each of the above-described solar cells was put in a temperature and humidity testing chamber which was set at a temperature of 85° C. and a humidity of 85%, and the conversion efficiency Eff was derived after 24 hours and 48 hours, respectively. As a result, in the solar cell produced using the electrically conductive paste in Comparative Example 2, the conversion efficiency Eff was 17.87% after 24 hours and 16.79% after 48 hours, respectively. In the solar cell produced using the electrically conductive paste in Example 9, the conversion efficiency Eff was 19.18% after 24 hours and 18.90% after 48 hours, respectively. These results are shown in FIG. 2. It can be seen from these results that it is possible to suppress the decrease of the conversion efficiency even after the weather resistance test, if the electrically conductive paste using the silver-coated copper powder having gold supported on the surface thereof is used for forming the busbar electrodes of the solar cell.

1. A method for producing a silver-coated copper powder, said method comprising the steps of:
preparing a copper powder, the surface of which is coated with a silver containing layer; and
adding the copper powder to a gold plating solution to cause gold to be supported on the surface of the copper powder coated with the silver containing layer.

2. A method for producing a silver-coated copper powder as set forth in claim 1, wherein said silver containing layer is a layer of silver or a silver compound.

3. A method for producing a silver-coated copper powder as set forth in claim 1, wherein the amount of said silver containing layer with respect to said silver-coated copper powder is not less than 5% by weight.

4. A method for producing a silver-coated copper powder as set forth in claim 1, wherein the amount of said gold with respect to said silver-coated copper powder is not less than 0.01% by weight.

5. A method for producing a silver-coated copper powder as set forth in claim 1, wherein said gold plating solution comprises a potassium gold cyanide solution.

6. A method for producing a silver-coated copper powder as set forth in claim 1, wherein said gold plating solution comprises a potassium gold cyanide solution which contains at least one selected from the group consisting of tripotassium citrate monohydrate, anhydrous citric acid and L-aspartic acid.

7. A method for producing a silver-coated copper powder as set forth in claim 1, wherein a particle diameter (D₅₀ diameter) corresponding to 50% of accumulation in cumulative distribution of said copper powder, which is measured by a laser diffraction particle size analyzer, is in the range of from 0.1 μm to 15 μm.

8. A silver-coated copper powder comprising:
a copper powder coated with a silver containing layer; and
gold supported on the surface of the copper powder coated with the silver containing layer.

9. A silver-coated copper powder as set forth in claim 8, wherein said silver containing layer is a layer of silver or a silver compound.

10. A silver-coated copper powder as set forth in claim 8, wherein the amount of said silver containing layer with respect to said silver-coated copper powder is not less than 5% by weight.

11. A silver-coated copper powder as set forth in claim 8, wherein the amount of said gold with respect to said silver-coated copper powder is not less than 0.01% by weight.

12. A silver-coated copper powder as set forth in claim 8, wherein a particle diameter (D₅₀ diameter) corresponding to 50% of accumulation in cumulative distribution of said copper powder, which is measured by a laser diffraction particle size analyzer, is in the range of from 0.1 μm to 15 μm.

13. An electrically conductive paste wherein a silver coated copper powder as set forth in claim 8 is used as an electric conductor.

14. An electrically conductive paste comprising:
a solvent;
a resin; and
a silver-coated copper powder as set forth in claim 8 as an electrically conductive powder.

15. A method for producing an electrode for solar cell, the method comprising the steps of:
applying an electrically conductive paste as set forth in claim 13, on a substrate; and
curing the electrically conductive paste to form an electrode on the surface of the substrate.
